(19) United States
(12) Patent Application Publication
(10) Pub. No.: US 2008/0197480 A1
(43) Pub. Date: Aug. 21, 2008

(54) Semiconductor device package with multi-chips and method of the same

(75) Inventors: Wen-Kun Yang, Hsin-Chu City (TW); Diann-Fang Lin, Hukou Township (TW)

Correspondence Address: BACON & THOMAS, PLLC, 625 SLATERS LANE, FOURTH FLOOR, ALEXANDRIA, VA, 22314, US

(73) Assignee: Advanced Chip Engineering Technology Inc., Hukou Township (TW)

(21) Appl. No.: 11/979,104

(22) Filed: Oct. 31, 2007

Related U.S. Application Data
(63) Continuation-in-part of application No. 11/707,042, filed on Feb. 16, 2007.

(51) Int. Cl. H01L 23/04; H01L 21/00

(52) U.S. Cl. 257/698; 438/113; 257/E23.181; 257/E21.001

(57) ABSTRACT

The present invention provides a semiconductor device package with the multi-chips comprising a substrate with a die receiving through hole, a conductive connecting through holes structure and coupled the first contact pads on an upper surface and second contact pads on a lower surface of the substrate through a conductive connecting through holes. A first die having first bonding pads is disposed within the die receiving through hole. A first adhesion material is formed under the die and a second adhesion material is filled in the gap between the die and sidewall of the die receiving though holes of the substrate. Then, a first conductive wire is formed to couple the first bonding pads and the first contact pads. Further, a second die having second bonding pads is attached on the first die. A second conductive wire is formed to couple the second bonding pads and the first contact pads. A plurality of dielectric layer is formed on the first and second bonding wire, the first and second die and the substrate.

### CROSS-REFERENCE

This application is a continuation-in-part (CIP) application of pending U.S. patent application Ser. No. 11/707,042, filed on Feb. 16, 2007.

### BACKGROUND OF THE INVENTION

1. Field of the Invention

This invention relates to a structure of semiconductor device package, and more particularly to a structure of semiconductor device package with multi-chips and method of the same, the structure can reduce the package size and improve the yield and reliability.

2. Description of the Prior Art

In recent years, the high-technology electronics manufacturing industries launch more feature-packed and humanized electronic products. Rapid development of semiconductor technology has led to rapid progress of a reduction in size of semiconductor packages, the adoption of multi-pin, the adoption of fine pitch, the minimization of electronic components and the like. The purposes and the advantages of wafer level package includes decreasing the production cost, decreasing the effect caused by the parasitic capacitance and parasitic inductance by using the shorter conductive line path, acquiring better SNR (i.e. signal to noise ratio).

Because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip ball grid array (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

In the manufacturing method, wafer level chip scale package (WLCSP) is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices. Further, WLCSP has an advantage of being able to print the redistribution circuit directly on the die by using the peripheral area of the die as the bonding points. It is achieved by redistributing an area array on the surface of the die, which can fully utilize the entire area of the die. The bonding points are located on the redistribution circuit by forming flip chip bumps so the bottom side of the die connects directly to the printed circuit board (PCB) with micro-spaced bonding points.

Although WLCSP can greatly reduce the signal path distance, it is still very difficult to accommodate all the bonding points on the die surface as the integration of die and internal components gets higher. The pin count on the die increases as integration gets higher so the redistribution of pins in an area array is difficult to achieve. Even if the redistribution of pins is successful, the distance between pins will be too small to meet the pitch of a printed circuit board (PCB). That is to say, such process and structure of prior art will suffer yield and reliability issues owing to the huge size of package. The further disadvantage of former method are higher costs and time-consuming for manufacture.

WLP technique is an advanced packaging technology, by which the die are manufactured and tested on the wafer, and then the wafer is singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For instance, the coefficient of thermal expansion (CTE) difference (mismatching) between the materials of a structure of WLP and the mother board (PCB) becomes another critical factor to mechanical instability of the structure. A package scheme disclosed by U.S. Pat. No. 6,271,469 suffers the CTE mismatching issue. It is because the prior art uses silicon die encapsulated by molding compound. As known, the CTE of silicon material is 2.3, but the CTE of molding compound is around 20-80. The arrangement causes chip location be shifted during process due to the curing temperature of compound and dielectric layers materials are higher and the inter-connecting pads will be shifted that will causes yield and performance problem. It is difficult to return the original location during temperature cycling (it caused by the epoxy resin property if the curing Temp near/over the Tg). It means that the prior structure package can not be processed by large size, and it causes higher manufacturing cost.

Further, some technical involves the usage of die that directly formed on the upper surface of the substrate. As known, the pads of the semiconductor die will be redistributed through redistribution processes involving a redistribution layer (RDL) into a plurality of metal pads in an area array type. The build up layer will increase the size of the package. Therefore, the thickness of the package is increased. This may conflict with the demand of reducing the size of a chip.

Moreover, the prior art suffers complicated process to form the “Panel” type package. It needs the mold tool for encapsulation and the injection of mold material. It is unlikely to control the surface of die and compound at same level due to warp after heat curing the compound, the CMP process may be needed to polish the uneven surface. The cost is therefore increased.

In view of the aforementioned, the present invention provides a new structure with multi-chips and method for a panel scale package (PSP) to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a structure of semiconductor device package and method of the same, which can provide a new structure of super thin package with stacking chips.

Another objective of the present invention is to provide a structure of semiconductor device package and method of the same, which can allow a better reliability due to the substrate and the PCB have the same coefficient of thermal expansion (CTE).

Still another objective of the present invention is to provide a structure of semiconductor device package and method of the same, which can provide a simple process for forming a semiconductor device package.

Yet another objective of the present invention is to provide a structure of semiconductor device package and method of the same, which can lower cost and higher yield rate.

Another objective of the present invention is to provide a structure of semiconductor device package and method of the same, which can provide a good solution for low pin count device.

The present invention provides a structure of semiconductor device package comprising a substrate with at least a die receiving through hole, a conductive connecting through holes structure and coupled the first contact pads on an upper surface and second contact pads on a lower surface of the substrate through the conductive connecting through holes; at least a first die having first bonding pads disposed within the die receiving through hole; a first adhesion material formed under the first die; a second adhesion material filled into the gap between the sidewall of first die and sidewalls of the die receiving though hole of the substrate; a first conductive wire formed to couple to the first bonding pads and the first contact pads; at least a second die having second bonding pads disposed on the first die; a second conductive wire formed to couple to the second bonding pads and the first contact pads; a die attached material formed under the second die; and a plurality of dielectric layer formed on the first and second conductive wires, the first and second die and the substrate.

The present invention provides a method for forming a semiconductor device package comprising providing at least a substrate with a die receiving through hole, a conductive connecting through holes structure and coupled the first contact pads on an upper surface and second contact pads on a lower surface of the substrate through the conductive connecting through holes; forming (printing) the patterned glues on the die redistribution tool; bonding the substrate on the patterned glues of the die redistribution tool; and redistributing desired at least first die having first bonding pads on a die redistribution tool with desired pitch by a pick and place fine alignment system, the active surface of first die be stuck by the patterned glues; filling a first adhesion material on the back side of the die (it maybe performed in wafer form before dicing saw); filling a second adhesion material into the space between the die edge (sidewall) and the die receiving through hole of the substrate; separating the “panel wafer” (panel wafer form means the substrate with embedded die and adhesion together) from the die redistribution tool by releasing the patterned glues; forming a first conductive wire to connect the first bonding pads and the first contact pads; placing and attached at least a second die having second bonding pads on the first die by die attached material (the die attached material can be preformed the attached tape in wafer form or printing the die attached material on the first die after completed the first conductive wire); forming a second conductive wire to connect the second bonding pads of second die and the first contact pads of substrate; connecting the first contact pads to the second contact pads by conductive connecting through holes (pre-formed in substrate); forming a multiple dielectric layers on the conductive wire and the active surface of the first die and second die and the upper surface of the substrate; then mounting the package structure (in panel form) on a tape to saw into individual die for singulation. It can be performed the final testing and/or burn-in process in panel wafer form before singulation.

The present invention provides a method for forming a semiconductor device package comprising providing a substrate with at least a die receiving through hole, conductive connecting through holes structure and couple the first contact pads on an upper surface and second contact pads on a lower surface of the substrate through the conductive connecting through holes; printing the patterned glues on the die redistribution tool; bonding the substrate on a die redistribution tool; redistributing desired at least first die having first bonding pads on the die redistribution tool with back side of the first die be stuck by patterned glues and desired pitch into the die receiving through hole of the substrate by a pick and place fine alignment system; forming a first conductive wire to connect the first bonding pads and the first contact pads; placing/attaching at least a second die (with adhesion tape on the back side of second die) having second bonding pads on the first die; forming a second conductive wire to couple the second bonding pads and the first contact pads; forming a dielectric layer on the active surface of the first and second die and upper surface of the substrate and the gap between the first die and sidewall of the die receiving through hole; separating the “panel” (panel form means substrate with the die and the adhesion material—in here is dielectric layer) from the die redistribution tool by releasing the patterned glues; and mounting the package structure (in panel form) on a tape to saw into individual die (semiconductor device) for singulation.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1a illustrates is a cross-section diagram of a structure of semiconductor device package according to one embodiment of the present invention (wire bonding type);

FIG. 1b illustrates is a cross-section diagram of a structure of semiconductor device package according to one embodiment of the present invention (RDL type);

FIG. 2a illustrates is a cross-section diagram of a structure of semiconductor device package according to another embodiment of the present invention;

FIG. 2b illustrates is a cross-section diagram of a structure of semiconductor device package according to another embodiment of the present invention;

FIG. 3a illustrates is a cross-section diagram of a structure of semiconductor device package according to another embodiment of the present invention (wire bonding type);

FIG. 3b illustrates is a cross-section diagram of a structure of semiconductor device package according to another embodiment of the present invention (RDL type);

FIG. 4 illustrates a bottom view diagram of a structure of semiconductor device package according to the present invention;

FIG. 5 illustrates a top view diagram of a structure of semiconductor device package according to one embodiment of the present invention;

FIGS. 6a-6d illustrate cross-section diagrams of a method of forming a semiconductor device package according to one embodiment of the present invention; and

FIGS. 7a-7g illustrate cross-section diagrams of a method of forming a semiconductor device package according to another embodiment of the present invention.

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

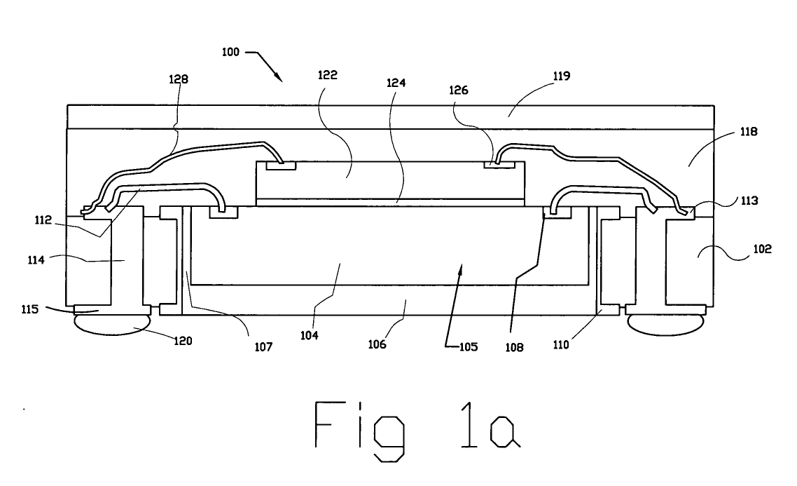

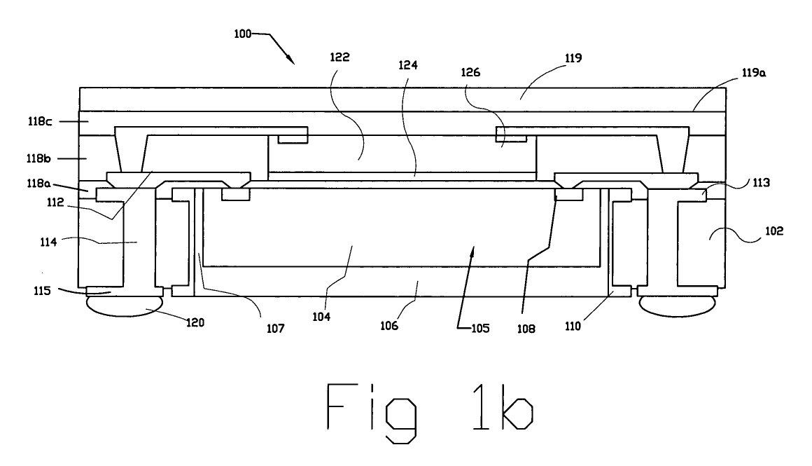

Referring to FIGS. 1a and 1b, they are cross-section diagrams of the structure of semiconductor device package 100 according to one embodiment of the present invention. The package 100 comprises a substrate 102, a first die 104, a die receiving through hole 105, a first adhesion material 106, a second adhesion material 107, first bonding pads 108, a metal or conductive layer 110, a first conductive wire 112, first contact pads 113, connecting through holes structure 114, second contact pads 115, a second die 122, second bonding pads 126, a die attached tape 124, a second conductive wire 128, a dielectric layer 118 and a plurality of conductive bumps 120; it shows multiple dielectric layers 118a, 118b and 118c of FIG. 1b by using build up layers structure and method.

In FIGS. 1a and 1b, the substrate 102 has a die receiving through hole 105 formed therein to receive a first die 104. The die receiving through hole 105 is formed from the upper surface of the substrate 102 through the substrate 102 to the lower surface of the substrate 102. The die receiving through hole 105 is pre-formed within the substrate 102. The first adhesion material 106 is coated (taped) under the lower surface of the first die 104, it can be performed in silicon wafer form before dicing saw, thereby sealing the first die 104. The second adhesion material 107 is also refilled within the space between the edge of first die 104 and the sidewalls of the die receiving through holes 105. It maybe uses the same material for both the first adhesion material 106 and the second adhesion material 107.

The substrate 102 further comprises the conductive connecting through holes structure 114 formed therein. The first contact pads 113 and the second contact pads 115 (for organic substrate) are respectively formed on the upper surface and lower surface of the conductive connecting through holes structure 114 and partial part of the upper surface and lower surface of the substrate 102. The conductive material is re-filled into the conductive connecting through holes structure 114 for electrical connection, it is pre-formed process once making the substrate 102.

Optional, a metal or conductive layer 110 is coated (by the sputtering or electro-less plating method) on the sidewall of the die receiving through hole 105, that is to say, the metal layer 110 is formed between the first die 104 surrounding by the second adhesion material 107 and the substrate 102. It can improve the adhesion strength between die edge and sidewall of the die receiving through hole 105 of the substrate 102 by using some particular adhesion materials, especially for the rubber type adhesion materials.

The first die 104 is disposed within the die receiving through holes 105 on the substrate 102. As know, first bonding pads 108 are formed within the upper surface of the first die 104. A first conductive wire 112 is formed to couple to the first bonding pads 108 and the first contact pads 113. The first conductive wire can be performed either wire bonding method or build up redistribution method for electrical connecting.

The present invention further comprises a second die 122 formed on a die attached material 124 and then placed/attached on the active surface of the first die 104 (or on the dielectric layer once using the build up layers structure). In other words, the second die 122 is placed/attached on the first die 104 to expose the first bonding pads 108 for electrical connection (if using the wire bonding method). The second die 122 has a plurality of second bonding pads 126 formed on the upper surface of the second die 122. A second conductive wire 128 is formed to couple to the second bonding pads 126 and the first contact pads 113 (it can be the bonding wire or the build up layers structure). Next, a dielectric layer 118 is formed to cover the first conductive wire 112, the second conductive wire 128, the upper surface of the first die 104 and the second die 122 and the substrate 102. It will be multiple dielectric layers structure 118a, 118b, 118c once using the build up layers structure and method as FIG. 1b.

Optionally, the build up layers (RDL) structure and process can be performed on the lower side of substrate with embedded chips to couple the second contact pads to the terminal pads, the terminal pads structure can be either BGA or LGA format.

Then, a plurality of conductive bumps 120 are formed and coupled to the terminal pads 115 by printing the solder paste (or placement the solder balls) on the surface, followed by performing re-flow process to reflow the solder paste. Accordingly, the first die 104 and the second die 122 can be electrically connected with the conductive bumps 120 via the conductive connecting through holes structure 114, the first conductive wire 112 and the second conductive wire 128.

The protection base 119 is employed to prevent the package from external force that may causes damage to the package, it includes the adhesion layer 119a to adhesive between the dielectric layer 118 and the protection base 119, and the top dielectric layer 118 may be used as function of adhesion layer 119a if the adhesion is strong enough. The metal layer 110 and the second adhesion material 107 act as buffer areas that absorb the thermal mechanical stress between the first die 104 and substrate 102 during temperature cycling due to the second adhesion material 107 has elastic (elongation) property. The aforementioned structure constructs LGA type package (peripheral type).

In one embodiment, the material of the substrate 102 includes epoxy type FR5, FR4, polyimide (PI) or BT (Bismaleimide triazine epoxy with the fiber glass inside). The material of the substrate 102 also can be metal, alloy, glass, silicon, ceramic or print circuit board (PCB). The alloy further includes alloy 42 (42% Ni-58% Fe) or Kovar (29% Ni-17% Co-54% Fe). Further, the alloy metal is preferably composed by alloy 42 that is a nickel iron alloy whose coefficient of expansion makes it suitable for joining to silicon chips in miniature electronic circuits and consists of nickel 42% and ferrous (iron) 58%. The alloy metal also can be composed by Kovar which consists of nickel 29%, cobalt 17% and ferrous (iron) 54%.

Preferably, the material of the substrate 102 is organic substrate likes epoxy type FR5, polyimide (PI), BT, PCB with defined through holes or Cu metal layers with pre etching circuit. Preferably, the coefficient of thermal expansion (CTE) is the same as the one of the mother board (PCB), and then the present invention can provide a better reliability structure due to the CTE of the substrate 102 is matching with the CTE of the PCB (or mother board) accordingly. Preferably, the organic substrate with high Glass transition temperature (Tg) are epoxy type FR5 or BT (Bismaleimide triazine) type substrate. The Cu metal (CTE around 16) can be used also. The glass, ceramic, silicon can be used as the substrate. The second adhesion material 107 is preferably formed of silicone rubber elastic materials; the epoxy resin also can be used too.

In one embodiment, the material of the first adhesion material 106 and the second adhesion material 107 include ultraviolet (UV) curing type and thermal curing type material, epoxy or rubber type material. The first adhesion material 106 also can be included the metal material. Further, the material of the dielectric layer 118 includes liquid compound, resin, silicone rubber for the wire bonding application and also can be benzocyclobutene (BCB), Siloxane polymer (SINR), or polyimide (PI) for the build up layers application.

In one embodiment, the material of the protection base 119 includes, but not limited to, FR5, polyimide (PI) or BT with the fiber glass inside. The protection base 119 can be attached on top of the dielectric layer to protect the package, and the protection base 119 also can be marked the character on the top by the laser process.

In one embodiment, the material of the die attached materials 124 includes, but not limiting to, elastic material. The die attached materials 124 for instant the attached tape has space balls inside which acts as buffer area that absorbs the thermal mechanical stress between the first die 104 and the second die 122 during temperature cycling and UV curing.

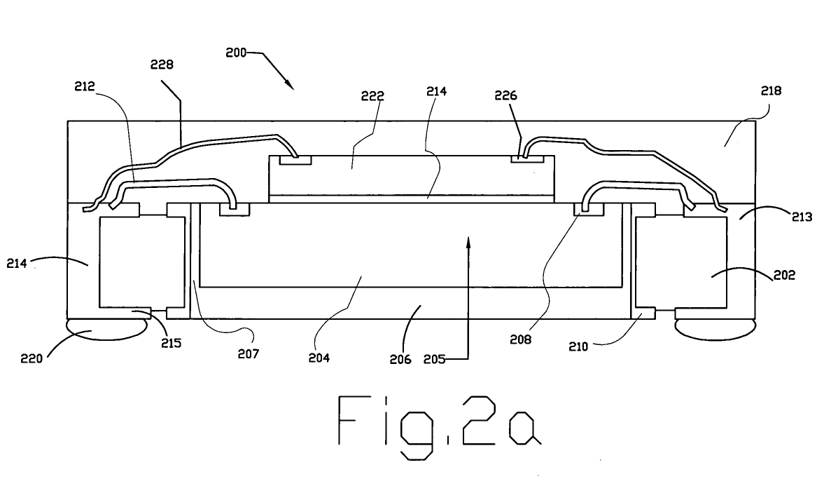

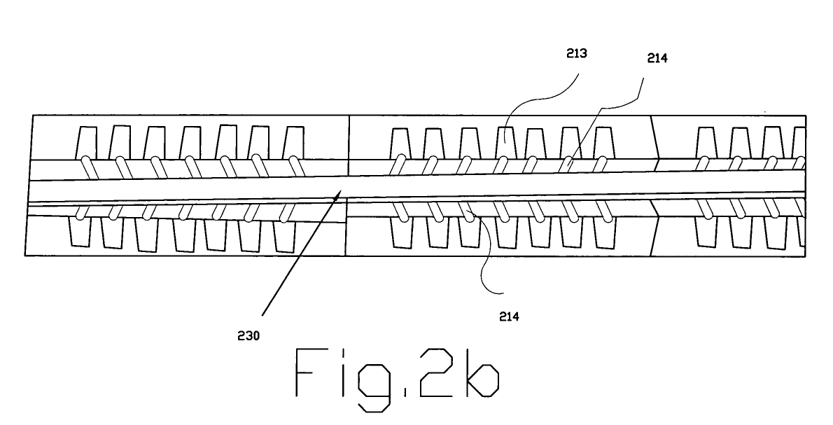

Referring to FIG. 2a, it is a cross-section diagram of a structure of semiconductor device package 200 according to another embodiment of the present invention. The substrate 202 comprises the conductive connecting through holes structure 214 formed on four sides of the substrate 202, that is to say, the connecting through holes structure 214 is respectively formed on both lateral sides of the substrate 202 (maybe four end sides). The first contact pads 213 and the second contact pads 215 are respectively formed on the upper surface and lower surface of the conductive connecting through holes structure 214 and partial part of the upper surface and lower surface of the substrate 202. The conductive material is re-filled into the connecting through holes structure 214 for electrical connection. Each individual package shares the half of conductive connecting through holes after completed the singulation.

Further, the package structure 200 comprises a second die 222 having a plurality of second bonding pads 226 formed on the upper surface of the second die 222. The second die 222 is formed on a die attached material 224, followed by placing/attaching the second die 222 on the active surface of the first die 204 (the second die 222 be attached on the first build up layers of the first die if using the build up layers process for forming the conductive wire). In other words, the second die 222 is placed on the first die 204 to expose the first bonding pads 208 for electrical connection (if using the wire bonding application). A second conductive wire 218 is formed to couple the second bonding pads 226 and the first contact pads 213. Then, optionally, forming the build up layers (RDL) on the lower side of substrate with embedded chips for coupling the second contact pads and the terminal pads and a plurality of conductive bumps 220 are coupled to the terminal pads 215. Accordingly, the first bonding pads 208 formed within the first die 204 and the second bonding pads 226 formed within the second die 222 can be electrically connected with the conductive bumps 220 by the conductive connecting through holes structure 214, the first conductive wire 212 and the second conductive wire 228.

Optionally, a metal or conductive layer 210 is coated on the sidewall of the die receiving through hole 205, namely, the metal layer 210 is formed between the first die 204 surrounding by the second adhesion material 207 and the substrate 202.

Further, various elements in the package 200 are similar to the elements in the package 100, as shown in FIGS. 1 and 2, and therefore, the detailed description is omitted.

In FIG. 2b, illustrates is a cross-section diagram of a structure of semiconductor device package 200 according to the present invention. The first contact pads 213 are formed over the conductive connecting through holes structure 214. The conductive connecting through holes structure 214 is located in the scribe line 230 area. In other words, each package has half through holes structure 214 after sawed (actually, the size is less than half due to some area was sawed off). The inside of the conductive through holes are filled by the conductive materials and/or the plus rest area is plugged by the epoxy resin. It can improve the solder join quality during SMT process and also can reduce the foot print. Similarly, the structure of half through holes structure 214 can be formed on the sidewall of the die receiving through hole 205 (does not show on the drawing), it can replace the conductive layer 210. Optionally, the above through holes structure 214 is also called the connecting trench.

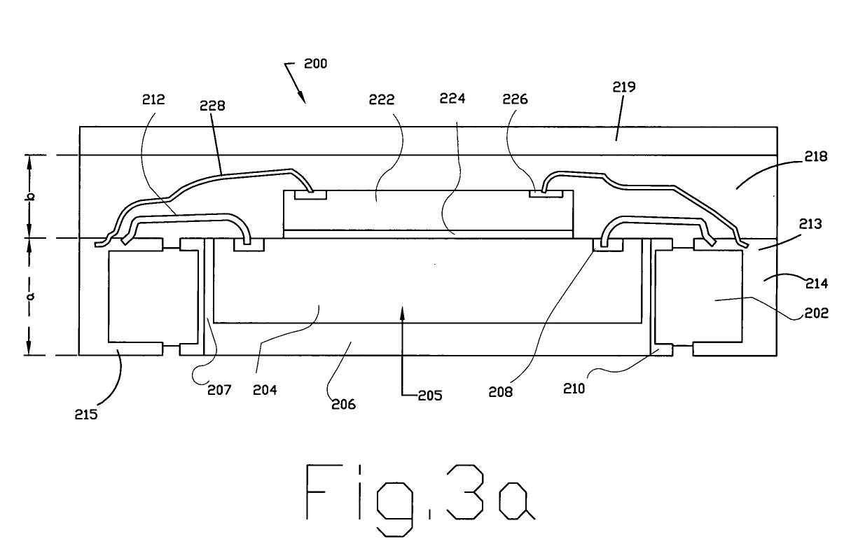

Referring to FIG. 3a and FIG. 3b, it is a cross-section diagram of a structure of semiconductor device package 200 according to the present invention. An alternative embodiment can be seen in FIGS. 3a and 3b, a package structure 200 can be formed without the conductive bumps 220 on the second terminal pads 215. The other parts are similar to FIG. 1a and FIG. 1b, therefore, the detailed description is omitted.

Preferably, the thickness a from the surface of the layer 118 to the upper surface of the substrate 102 is approximately 118-218 μm. The thickness b from the upper surface of the substrate 102 is approximately 60-150 μm. Accordingly, the present invention can offer a super thin structure having a thickness less than 500 μm, and the package size is approximately around the die size plus 0.5 mm to 1 mm per side to form a chip scale package (CSP) by using the conventional process of print circuit board.

Referring to FIG. 4, it illustrates a bottom view diagram of a structure of semiconductor device package 100 according to the present invention. The back side of the package 100 includes the substrate 102 (solder mask layer is not showed on the drawing) and the second adhesion material 107 formed therein and surrounded by a plurality of second contact pads 115. Optionally, the package 100 comprises a metal layer 150 sputtering or electro-plating on back side of the first die 104 to replace the first adhesion material 106, it maybe enhance the thermal conductivity, as shown in the external dotted area. The internal dotted area is an indicated area as the area of the second die 122. The metal layer 150 can be solder join with printed circuit board (PCB) by solder paste, it can exhaust the heat (generate by die) through the copper metal of print circuit board.

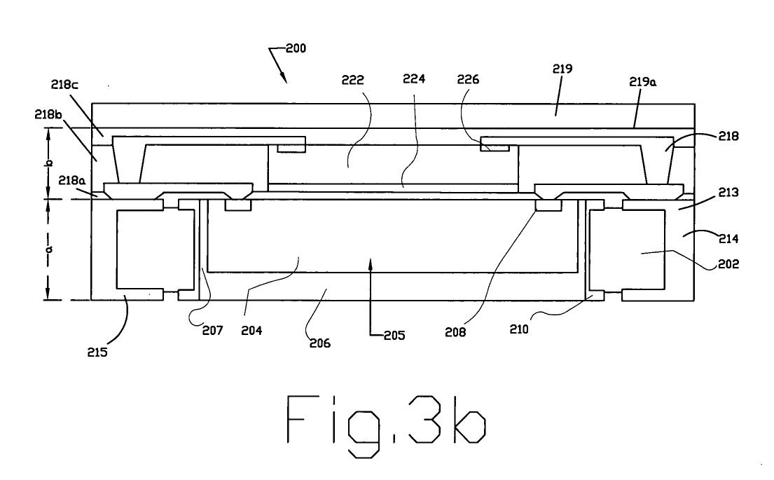

Referring to FIG. 5, it illustrates a top view diagram of a structure of semiconductor device package 100 according to the present invention. The top side of package 100 includes the substrate 102, a first die 104 formed on the first adhesion material 106. A plurality of first contact pads 113 are formed surrounding around the edge areas of the substrate 102. The first conductive wire 112 is formed to couple the first bonding pads 108 and the first contact pads 113. Further, a second die 122 is formed on the first die 104 to expose the first bonding pads 108 (for wire bonding application). The second conductive wires 128 couple the second bonding pads 126 to the first contact pads 113. It is noted that the first conductive wire 112 and the second conductive wire 128 are invisible after the formation of the dielectric layer 118 and the protection base 119.

Otherwise, the package 100 can be applied to higher pin counts. The embodiment is similar to FIG. 5, therefore, the detailed description is omitted. Accordingly, the peripheral type of the present invention can provide a good solution for low pin count device.

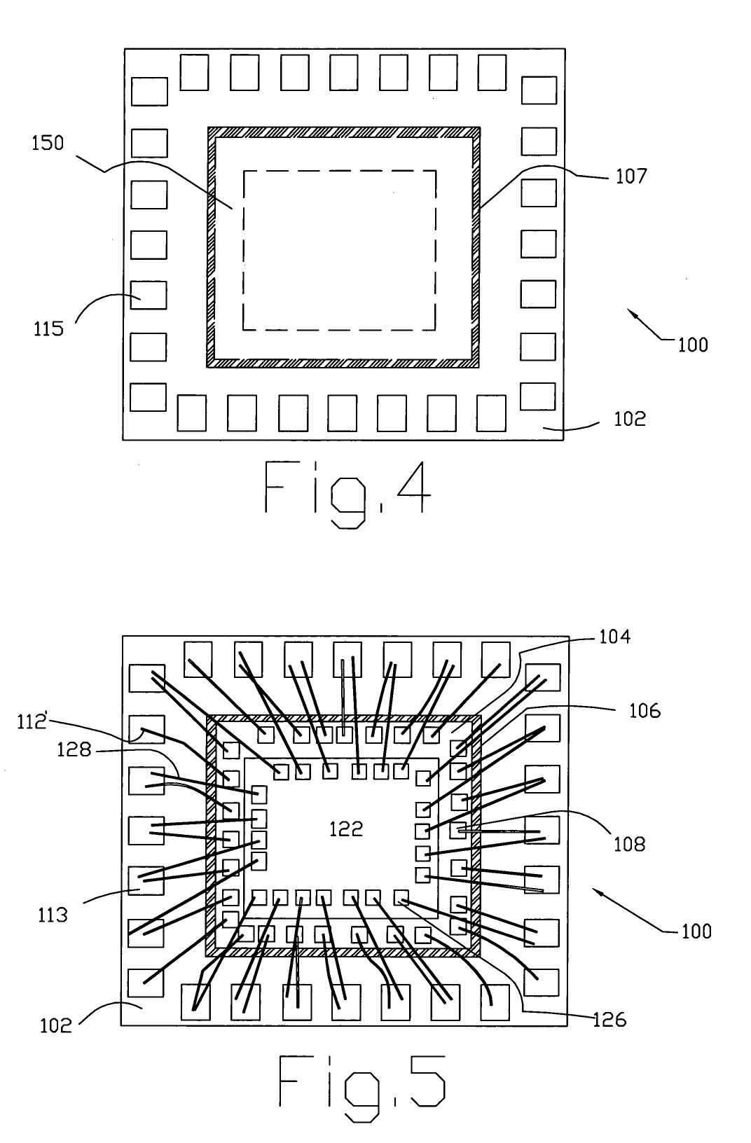

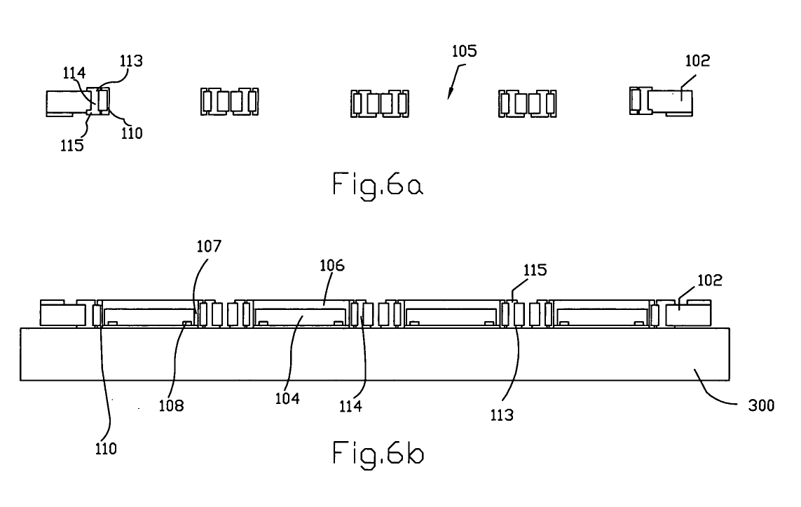

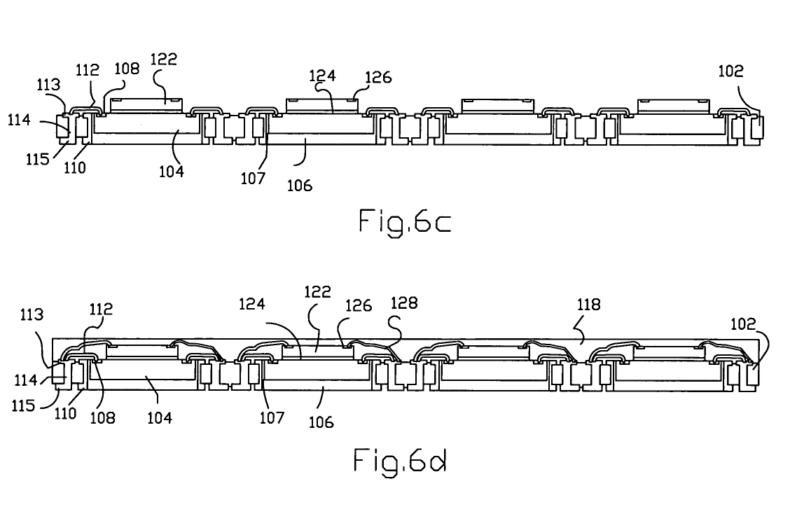

According to the aspect of the present invention, the present invention further provides a method for forming a semiconductor device package 100 with multi-chips, such as the first die 104 and the second die 122. Refer to FIGS. 6a-6d, they illustrate a cross-section diagrams of a method of forming a semiconductor device package 100. The steps are as follows and the following steps.

First, the substrate 102 with the die receiving through holes 105, conductive connecting through holes structure 114 and the first contact pads 113 on an upper surface and the second contact pads 115 on a lower surface of the substrate 102 is provided, wherein the die receiving through holes 105 and the connecting through holes structure 114 and the first contact pads 113 and the second contact pads 115 are preformed within the substrate 102, as shown in FIG. 6a. The die redistribution tool 300 with alignment pattern formed thereon is provided and the patterned glues are printed on the tool (not shown in the drawing). The substrate 102 is bonding to the die redistribution tool 300. The desired first die 104 having first bonding pads 108 are redistributed on a die redistribution tool 300 with desired pitch into the die receiving hole 105 of the substrate 102 by a pick and place fine alignment system, and the first die is stuck on the die redistribution tool by the patterned glues, as shown in FIG. 6b, that is to say, the active surface of the die 104 is sticking on the die redistribution tool 300 stuck by patterned glues (not shown). After the second adhesion material 107 filled into the space between the first die 104 (sidewall) and the first adhesion material 106 on back side of the first die 104, the first and second adhesion material 106 and 107 are cured, in this application, it maybe the same materials for the first adhesion material 106 and the second adhesion material 107. Then, the package structure (panel wafer form) is separated from the die redistribution tool 300.

After cleaning the top surface of the first bonding pads 108 and the first contact pads 113 (the pattern glues may residue on the surface of first bonding pads 108 and first contact pads 113 after releasing the patterned glues), the first conductive wire 112 is formed to connect the first bonding pads 108 to the first contact pads 113, as shown in FIG. 6c, the conductive wire can be formed by the wire bonding process or build up layers process. The build up layers process can be applied to the dielectric layer on the upper surface and used to open the first bonding pads, then sputtering the seed metal layers, forming the PR to form the trace pattern and E-plating the metal on the pattern, follow up striping the PR, etching the wet metal to form the RDL trace, coating or printing the second dielectric layer etc. Subsequently, a second die 204 is formed on the die attached material 214 and followed by placing and attaching the die 204 on the first die 202 (the second dielectric layer may be used as an attached material if the adhesion properties good enough). The second die 204 does not cover the first bonding pads 108 if applying the wire bonding application, so that the first bonding pads 108 are exposed for electrical connection. The second die 202 has the second bonding pads 126 formed thereon. Then, the second conductive wire 128 is coupled the second bonding pads 126 and the first contact pads 113, the conductive wire process can be same as the first conductive wire process.

Next, the dielectric layer 118 is coated (or molding or printing or dispensing) and cured on the active surface of the first die 104, the second die 122 and upper surface of the substrate 102 in order to protect the first bonding wire 112, the first die 104, the second bonding wire 128, the second die 122 and the substrate 102, as shown in FIG. 6d. The multiple dielectric layers are used for the build up layers process, and optionally, the protection base 119 is adhered with the dielectric layer by the adhesion layer 119a to protect the package and is marked on the top surface by laser if applying the build up layers process to form the conductive wire. The terminal contact pads are formed on the second contact pads 115 by printing the solder paste (or ball). Optionally, the build up layers process also can be applied on the lower surface of substrate with embedded chips inside and couples the second contact pads to the terminal pads (the terminal pads maybe the array format). Then, the plurality of conductive bumps 120 are formed by an IR reflow method and coupled to the second contact pads 115 or terminal pads. Subsequently, the package structure (in panel wafer form) is mounting on a tape 302 for the die singulation process. Optionally, the panel wafer final testing or panel wafer burn-in process can also be applied before package singulation.

Optionally, a metal or conductive layer 110 is formed on the sidewall of die receiving through hole 105 of the substrate 102, the metal is pre-formed during the manufacture of the substrate by the electro-less plating or sputtering process plus the PR process etc. A metal film (or layer) can be sputtered or plated on the back side of the first die 104 as the first adhesion material 106 for better thermal management inquiry.

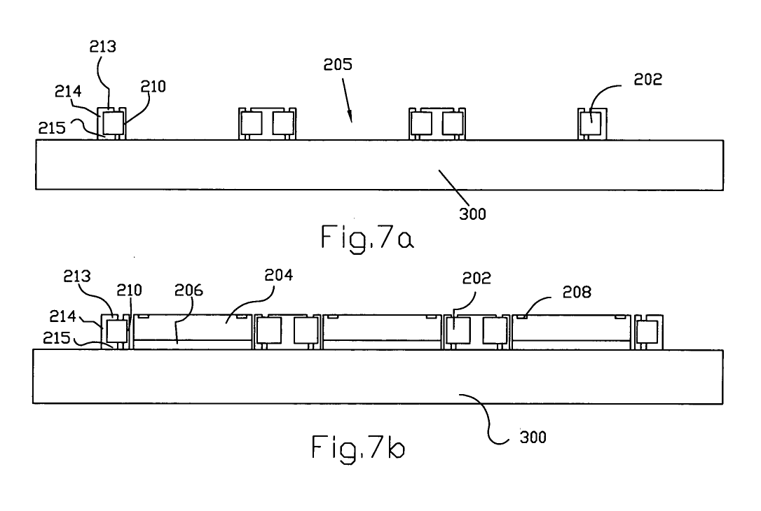

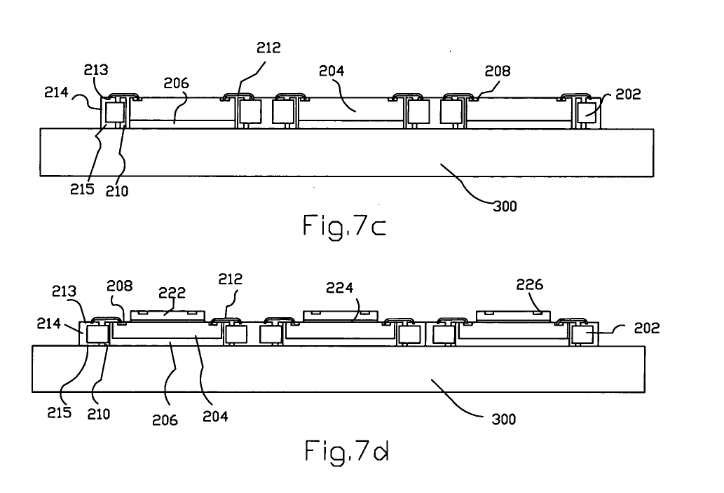

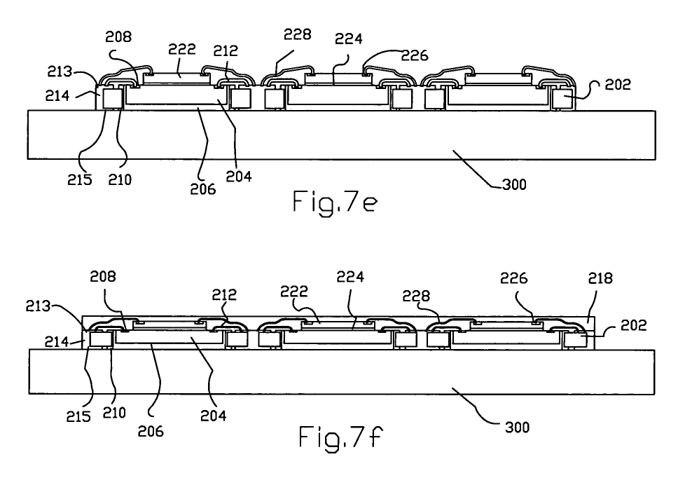

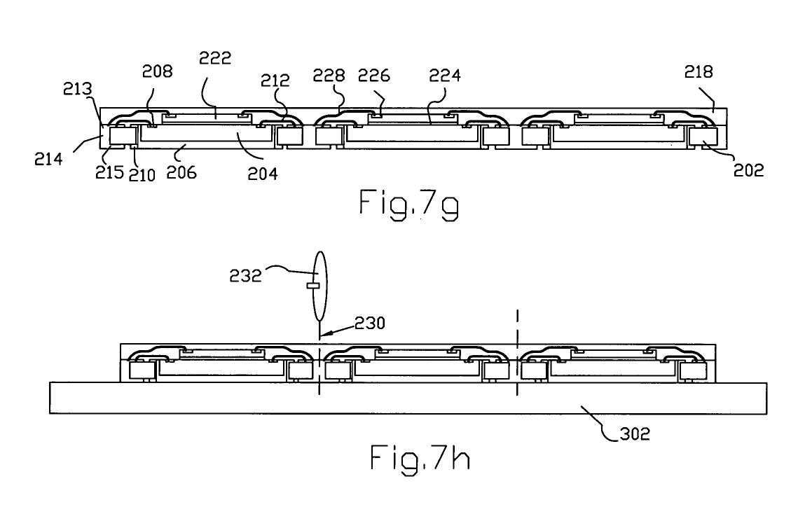

According to another aspect of the present invention, the present invention also provides another method for forming a semiconductor device package 200 with the die receiving through holes 205 and the conductive connecting through holes structure 214. Refer to FIGS. 7a-7h they illustrate cross-section diagrams of a method of forming a semiconductor device package 200 according to the present invention

The steps of forming the package 200 comprises providing a substrate 202 with die receiving through holes 205, conductive connecting through holes structure 215 and the first contact pads 213 on an upper surface and the second contact pads 215 on a lower surface of the substrate 202. The substrate 202 is bonding to a die redistribution tool 300, as shown in FIG. 7a. In other words, the active surface (for solder join) of the substrate 202 is sticking on the die redistribution tool 300 printed by patterned glues (not shown). The desired first die 204 has first bonding pads 208 formed on the upper surface of the first die 204, and the first adhesion material 206 (optional—it maybe the adhesion tape) is formed on the back side of the first die 204, as shown in FIG. 7b. The first die 204 is redistributed on the die redistribution tool 300 with back side of die stuck by the patterned glues and desired pitch by a pick and place fine alignment system. Then, the first bonding wire 212 is formed to connect the first bonding pads 208 to the first contact pads 213, as shown in FIG. 7c.

Subsequently, the second die 222 is formed on the die attached tape 224 and then formed on the first die 204 to expose the first bonding pads 208, as shown in FIG. 7d. The second die 222 has the second bonding pads 226 formed within the second die 222. Then, the first adhesion material 206 and the die attached tape 224 are cured. The second bonding wire 228 is formed to couple the second bonding pads 226 and the first contact pads 213, as shown in FIG. 7e.

Next, the dielectric layer 218 is formed on the active surface of the first die 204, the second die 222 and upper surface of the substrate 202 to fully cover the first bonding wire 212 and the second bonding wire 228 and fill into the gap between die edge and sidewall of die receiving through hole 205 as second adhesion material 207, as shown in FIG. 7f, and then the dielectric layer 218 is cured. After the package structure separated from the die redistribution tool 300 by releasing the patterned glues, the back side of the substrate 202 and the first adhesion material 206 are cleaned (to clean up the residue of the patterned glues), as shown in FIG. 7g.

Alternatively, the terminal contact pads are formed on the second contact pads 215 by printing the solder paste (or ball). Optionally, the plurality of conductive bumps 220 are formed and coupled to the second contact pads 215. Subsequently, the package structure 200 is mounted on a tape 302 for die singulation.

Optionally, a metal or conductive layer 210 is formed on the sidewall of die receiving through hole 205 of the substrate 202, it is pre-formed as mentioned above. Another process is used to form the first adhesion material 206 by using the steps including seed metal sputtering, patterning, electro-plating (Cu), PR stripping, metal wet etching etc. to achieve the metal layer 150.

In one embodiment, a conventional sawing blade 232 is used during the singulation process. The blade 232 is aligned to the scribe line 230 to separate the dice (the semiconductor device package) into individual die during the singulation process.

In one embodiment, the step of forming the conductive bumps 120 and 220 are performed by an infrared (IR) reflow method.

It is noted that the material and the arrangement of the structure are illustrated to describe but not to limit the present invention. The material and the arrangement of the structure can be modified according to the requirements of different conductions.

According to the aspect of the present invention, the present invention provides a structure of semiconductor device with the die receiving through hole and the conductive connecting through holes structure, that provides a structure of super thin package which the thickness is less than 500 μm and the package size is slight large than the die size. Further, the present invention provides a good solution for low pin count device for the peripheral type format application. The present invention provides a simple method for forming a semiconductor device package which can improve the reliability and yield. Moreover, the present invention further provides a new structure that has multi-chips with stacking structure, and therefore can also minimize the size of chip scale package structure and lower costs due to the lower cost material and the simple process. Therefore, the super thin chip scale package structure and method of the same disclosed by the present invention can provide unexpected effect than prior art, and solve the problems of prior art. The method may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

1. A structure of semiconductor device package, comprising:
a substrate with at least a die receiving through hole, a conductive connecting through holes structure and coupled to the first contact pads on an upper surface and second contact pads on a lower surface of said substrate through said a conductive connecting through holes;
at least a first die having first bonding pads disposed within said die receiving through hole;
a first adhesion material formed under said first die;
a second adhesion material filled in the gap between said first die and sidewalls of said die receiving though hole of said substrate;
a first conductive wire formed to couple to said first bonding pads and said first contact pads;
a die attached material formed under said second die;
at least a second die having second bonding pads attached on said first die;
a second conductive wire formed to couple to said second bonding pads and said first contact pads; and
a plurality of dielectric layers formed on said first and second conductive wire, said first and second die and said substrate.

2. The structure in claim 1, wherein said first and second conductive wires include redistribution layers(RDL) formed on the lower surface of said substrate with embedded die to couple terminal pads and said second contact pads.

3. The structure in claim 2, further comprising a plurality of conductive bumps coupled to said terminal pads, wherein said plurality of conductive bumps can be electrically connected with said bonding pads through said conductive connecting through holes structure.

4. The structure of claim 1, further comprising a protection base formed on the top surface of said plurality of dielectric layers, wherein the material of said protection base includes FR4, FR5, polyimide (PI), BT (Bismaleimide triazine) or metal.

5. The structure of claim 1, wherein the material of said die includes semiconductor chips, passive components and electrical devices.

6. The structure of claim 1, wherein said conductive wire includes the bonding wire and the redistribution layers (RDL), wherein said redistribution layers structure formed in said multiple dielectric layers.

7. The structure in claim 1, further comprising a metal or conductive layer formed on side walls of said die receiving through hole of said substrate.

8. The structure in claim 1, wherein said conductive connecting through holes structure is formed lateral side of said substrate (half through holes structure).

9. The structure in claim 1, wherein material of said substrate includes epoxy type FR5/FR4, polyimide (PI), BT, metal, alloy, glass, silicon, ceramic or print circuit board (PCB).

10. The structure in claim 1, wherein material of said first adhesion material and second adhesion material include UV curing type and thermal curing type material, epoxy or rubber type material, wherein material of said first adhesion material include a metal sputtering and/or electro-plating on back side of said first die.

11. The structure in claim 1, wherein material of said die attached material includes elastic material.

12. The structure in claim 1, wherein material of said dielectric layer include liquid compound, resin, silicone rubber, benzocyclobutene (BCB), Siloxane polymer (SINR) or polyimide (PI).

13. A method for forming a semiconductor device package, comprising:
providing a substrate with at least a die receiving through hole, a conductive connecting through holes structure and coupled the first contact pads on an upper surface and second contact pads on a lower surface of said substrate through said a conductive connecting through holes;
printing the patterned glues on die redistribution tool;
bonding said substrate on said die redistribution tool by said patterned glues;
redistributing desired at least first die having first bonding pads on said die redistribution tool by said patterned glues with desired pitch by a pick and place fine alignment system;
forming a first adhesion material on the back side of said first dice;
filling a second adhesion material into the space between said dice edge and said dice receiving through hole of said substrate;
separating package structure from said die redistribution tool by releasing said patterned glues;
forming a first conductive wire to connect said first bonding pads to said first contact pads;
attaching at least a second die having second bonding pads on said first die;
forming a second conductive wire to connect said second bonding pads and said first contact pads;
forming a multiple dielectric layer on the active surface of said first and second die and upper surface of said substrate; and
mounting said package structure on a tape to saw into individual die for singulation.

14. The method of claim 13, wherein said conductive wire includes redistribution layers (RDL) formed on said lower surface of said substrate with embedded die to couple the terminal pads and said second contact pads.

15. The method in claim 13, further comprising a step of welding a plurality of soldering bumps on said terminal pads, wherein said step of forming said soldering bumps is performed by an infrared (IR) reflow method.

16. The method of claim 13, further comprising a step of formed protection base on the top surface of multiple dielectric layers by adhesion material.

17. The structure of claim 13, wherein the conductive wire includes the bonding wire or the redistribution layers (RDL), wherein said redistribution layers process includes forming dielectric layer, opening the bonding pads and contact pads then sputtering the seed metal layers, photo-resisting to form the conductive wire pattern, E-plating the conductive wire, stripping the PR, etching the seed metal to final form conductive wire as redistribution layers.

18. The method in claim 13, further comprising a step of sticking active surface of said first die on said die redistribution tool printed by said patterned glues.

19. The method in claim 13, further comprising a step of curing said first and second adhesion material.

20. The method in claim 13, further comprising a die attached tape formed under said second die, wherein material of said die attached tape includes elastic material.

21. The method in claim 13, further comprising a step of curing said dielectric layer.

22. The method in claim 13, further comprising a step of forming a metal or conductive layer on the sidewall of said die receiving through hole of said substrate.

23. The method in claim 13, further comprising a step of cleaning top surface of said package before forming said conductive wire.

24. A method for forming a semiconductor device package, comprising:
providing a substrate with at least a die receiving through hole, a conductive connecting through holes structure and couple the first contact pads on an upper surface and
second contact pads on a lower surface of said substrate through said a conductive connecting through holes;
printing the patterned glues on die redistribution tool;
bonding said substrate on said die redistribution tool by said patterned glues;
redistributing desired at least first die having first bonding pads on said die redistribution tool with back side of said die stuck by said patterned glues and desired pitch by a pick and place fine alignment system;
forming a first bonding wire to connect said first bonding pads to said contact pads;
placing at least a second die having second bonding pads disposed on said first die;
forming a second bonding wire to connect said second bonding pads and said first contact pads;
forming a dielectric layer on the active surface of said first and second die and upper surface of said substrate and fill into the gap between dice edge and sidewall of said die receiving through hole of said substrate;
separating said package structure from said die redistribution tool by releasing said patterned glues; and
mounting said package structure on a tape to saw into individual die for singulation.

25. The method in claim 24, further comprising a step of welding a plurality of conductive bumps on said second contact pads, wherein said step of forming said conductive bumps is performed by an infrared (IR) reflow method.

26-29. (canceled)
